(19) United States
(12) Patent Application Publication
(10) Pub. No.: US 2025/0293483 A1
(43) Pub. Date: Sep. 18, 2025

(54) OPTOELECTRONIC SEMICONDUCTOR COMPONENT AND METHOD FOR PRODUCING AN OPTOELECTRONIC SEMICONDUCTOR COMPONENT

(71) Applicant: ams-OSRAM International GmbH, Regensburg (DE)

(72) Inventors: Christoph Eichler, Donaustauf (DE); Teresa Wurm, Mintraching (DE); Bruno Jentzsch, Regensburg (DE)

(21) Appl. No.: 18/859,977

(22) PCT Filed: Mar. 31, 2023
(86) PCT No.: PCT/EP2023/058457

§ 371 Date: Oct. 24, 2024

(30) Foreign Application Priority Data
May 2, 2022 (DE) 10 2022 110 693.4

(51) Int. Cl. H01S 5/20; H01S 5/042; H01S 5/22; H01S 5/34; H01S 5/40

(52) U.S. Cl. CPC H01S 5/2036; H01S 5/0421; H01S 5/221; H01S 5/3416; H01S 5/4025

(57) ABSTRACT

In an embodiment an optoelectronic semiconductor component includes a semiconductor body having an n-conducting region, a p-conducting region and an active region configured to emit electromagnetic radiation, the active region arranged between the n-conducting region and the p-conducting region, wherein the p-conducting region comprises a spacer region and a p-doped doping region, wherein the spacer region is arranged between the doping region and the active region and comprises a first spacer layer comprising aluminum, and wherein a vertical extension of the doping region corresponds to at most one third of a vertical extension of the spacer region.

### CROSS-REFERENCE TO RELATED APPLICATIONS

This patent application is a national phase filing under section 371 of PCT/EP2023/058457, filed Mar. 31, 2023, which claims the priority of German patent application 102022110693.4, filed May 2, 2022, each of which is incorporated herein by reference in its entirety.

### TECHNICAL FIELD

An optoelectronic semiconductor component and a method for producing an optoelectronic semiconductor component are disclosed. The optoelectronic semiconductor component is in particular configured to generate electromagnetic radiation, for example light perceptible to the human eye. In particular, the semiconductor component is a laser component which is configured to emit coherent electromagnetic radiation by stimulated emission.

### SUMMARY

Embodiments provide an optoelectronic semiconductor component which has a particularly high efficiency.

Further embodiments provide a method for producing an optoelectronic semiconductor component which has a particularly high efficiency.

According to at least one embodiment, the optoelectronic semiconductor component comprises a semiconductor body with an n-conducting region, a p-conducting region and an active region configured to emit electromagnetic radiation, wherein the active region is arranged between the n-conducting region and the p-conducting region. In particular, the semiconductor body comprises a monolithically grown semiconductor layer sequence.

For example, the p-conducting region comprises at least one semiconductor layer that is p-doped, and the n-conducting region comprises at least one semiconductor layer that is n-doped. Here and hereinafter, “p-doped” refers to semiconductor materials with dopant atoms that act as electron acceptors, while “n-doped” refers to semiconductor materials with dopant atoms that act as electron donors.

The active region may comprise a double heterostructure, a single quantum well structure, a multi-quantum well structure or one or more quantum dot layers. A multi-quantum well structure comprises a plurality of quantum well layers separated by barrier layers. The barrier layers preferably have a larger bandgap than the quantum well layers. The arrangement of quantum well layers and barrier layers results in confinement of electrical charges in the quantum well layers, resulting in discrete energy values for the confined electrical charges. Preferably, the multi-quantum well structure comprises at least two and at most five quantum well layers.

The active region is configured to emit electromagnetic radiation in a spectral range between infrared light and ultraviolet light. Preferably, the active region is configured to emit electromagnetic radiation in a spectral range between green light and ultraviolet light.

According to at least one embodiment, the p-conducting region comprises a spacer region and a p-doped doping region. For example, the doping region is designed for external electrical contacting of the semiconductor body. For example, a solder metal can be in direct contact with the doping region.

The doping region preferably comprises a semiconductor material that is provided with dopant atoms that act as electron acceptors. The spacer region is only lightly doped or not doped, for example. Preferably, the spacer region is formed with or consists of a nominally undoped semiconductor material. In other words, no dopant atoms are intentionally introduced into the semiconductor material of the spacer region. The spacer region may contain impurity atoms that are unintentionally introduced into the spacer region, for example, during epitaxial growth of the spacer region. These impurity atoms can act as dopants in the semiconductor material of the spacer region. Preferably, the concentration of impurity atoms is low, so that the concentration of free charge carriers in the unintentionally doped semiconductor material does not exceed, for example, 10¹⁷ per cm³ without an applied electrical voltage.

According to at least one embodiment of the optoelectronic semiconductor component, the spacer region is arranged between the doping region and the active region and comprises a first spacer layer comprising aluminum. The spacer layer is formed, for example, with a semiconductor material comprising aluminum. Advantageously, a semiconductor layer formed with aluminum may have a particularly high bandgap and thus exhibit advantageously low optical absorption.

According to at least one embodiment, the optoelectronic semiconductor component comprises:
a semiconductor body having an n-conducting region, a p-conducting region and an active region configured to emit electromagnetic radiation, wherein
the active region is arranged between the n-conducting region and the p-conducting region,
the p-conducting region comprises a spacer region and a p-doped doping region,
the spacer region is arranged between the doping region and the active region and comprises a first spacer layer comprising aluminum.

An optoelectronic semiconductor component described herein is based, inter alia, on the following considerations: During operation of an optoelectronic semiconductor component, undesirable internal absorption losses may occur. Internal absorption losses are caused, among other things, by optical absorption of electromagnetic radiation in the semiconductor layers that are provided for electrically conducting a p-conducting region, for example a p-doped doping region near an active region. Such internal losses can severely impair the overall efficiency of the component and contribute to undesirably high heat generation.

The optoelectronic semiconductor component described here makes use, among other things, of the idea of arranging a spacer region between the active region and the p-doped doping region. With the help of the spacer region, electromagnetic radiation generated in the active region can be shielded from the strongly absorbing p-doped doping region. In this way, optical absorption can be reduced or prevented. As a result, a semiconductor component with particularly low internal losses and consequently an advantageously increased efficiency can be produced.

According to at least one embodiment of the optoelectronic semiconductor component, a vertical extension of the doping region corresponds to at most one third, preferably at most one fifth, particularly preferably at most one eighth of the vertical extension of the spacer region. Here and in the following, the vertical direction is considered to be a direction parallel to a stacking direction of the semiconductor body. The stacking direction is the direction in which the various semiconductor regions of the semiconductor body are stacked on top of each other. A small vertical extension of the doping region relative to the spacer region can advantageously result in a particularly low optical absorption in the semiconductor component.

According to at least one embodiment of the optoelectronic semiconductor component, the semiconductor body is formed with a III/V compound semiconductor material, in particular a nitride compound semiconductor material. A III/V compound semiconductor material comprises at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. Such a binary, ternary or quaternary compound may also have, for example, one or more dopants and additional components.

“Based on nitride compound semiconductor material” in the present context means that the semiconductor body or at least a part thereof, particularly preferably at least the active region and/or a growth substrate wafer, comprises or consists of a nitride compound semiconductor material, preferably AlₙGaₘIn₁₋ₙ₋ₘN, where 0≤n≤1, 0≤m≤1 and n+m≤1. This material does not necessarily have to have a mathematically exact composition according to the above formula. Rather, it can, for example, comprise one or more dopants as well as additional components. For the sake of simplicity, however, the above formula only contains the essential components of the crystal lattice (Al, Ga, In, N), even if these may be partially replaced and/or supplemented by small amounts of other substances.

According to at least one embodiment of the optoelectronic semiconductor component, the spacer region comprises a second spacer layer. The second spacer layer is formed, for example, with a nominally undoped semiconductor material. Preferably, for electromagnetic radiation generated in the active region during operation, a refractive index of the second spacer layer is higher than a refractive index of the first spacer layer. This advantageously results in better guidance of the electromagnetic radiation in the vertical direction.

According to at least one embodiment of the optoelectronic semiconductor component, the spacer region comprises a third spacer layer. The third spacer layer is formed, for example, with a nominally undoped semiconductor material. Preferably, for electromagnetic radiation generated in the active region during operation, a refractive index of the third spacer layer is higher than a refractive index of the first and second spacer layers. This advantageously results in better guidance of the electromagnetic radiation in the vertical direction.

According to at least one embodiment of the optoelectronic semiconductor component, the spacer region comprises a plurality of spacer layers, each with different refractive indices and bandgaps. Advantageously, this results in a particularly efficient semiconductor component.

According to at least one embodiment of the optoelectronic semiconductor component, the second and third spacer layers are formed with a semiconductor material selected from the following group: GaN, InGaN.

According to at least one embodiment of the optoelectronic semiconductor component, an average n-dopant concentration in the spacer region is less than 10²⁰ cm⁻³, preferably less than 10¹⁹ cm⁻³, particularly preferably less than 10¹⁸ cm⁻³. An average dopant concentration is defined here and in the following as a dopant concentration averaged over the entire spacer region. A low n-dopant concentration advantageously enables particularly low optical absorption in the spacer region.

According to at least one embodiment of the optoelectronic semiconductor component, an average p-dopant concentration in the spacer region is less than 10¹⁹ cm⁻³, preferably less than 10¹⁸ cm⁻³, particularly preferably less than 10¹⁷ cm⁻³. A low p-dopant concentration advantageously enables particularly low optical absorption in the spacer region. For example, the first spacer region is doped with p-dopants and n-dopants at the same time and an added dopant concentration is less than 10¹⁹ cm⁻³, preferably less than 10¹⁸ cm⁻³, particularly preferably less than 10¹⁷ cm⁻³. Preferably, the spacer region has a lower dopant concentration than 10¹⁷ cm⁻³.

According to at least one embodiment of the optoelectronic semiconductor component, the n-conducting region comprises a first waveguide, a second waveguide and a first cladding layer, wherein the first and second waveguides are arranged between the first cladding layer and the active region. Advantageously, the first and second waveguides have a higher refractive index than the first cladding layer for electromagnetic radiation generated in the active region during operation. Peak doping regions are preferably introduced at an interface between the first waveguide and the second waveguide and/or at an interface of the second waveguide to the first cladding layer. Peak doping regions are locally delimiting excesses of a dopant concentration.

In particular, a concentration of an n-dopant at the interfaces between the first and second waveguides and between the second waveguide and the first cladding layer is increased relative to the immediately adjacent region. For example, a doping of the peak doping region increases in the direction away from the active region by at least a first percentage value and decreases again by at least a second percentage value, wherein the first and second percentage values are greater than 10% of a maximum doping of the peak doping region. Advantageously, a voltage drop in the n-conducting region can thus be reduced or avoided.

According to at least one embodiment of the optoelectronic semiconductor component, the first cladding layer has a higher n-doping than the first waveguide and the second waveguide. Here and in the following, doping is defined as an average dopant concentration within an entire structural element. For example, the n-doping of the first cladding layer corresponds to the average dopant concentration of the entire first cladding layer. For example, the n-doping of the first waveguide corresponds to the average dopant concentration within the entire first waveguide. A relatively low doping of the first and second waveguide causes, among other things, a reduction in the internal absorption losses of the semiconductor component.

According to at least one embodiment of the optoelectronic semiconductor component, an aluminum content of the first spacer layer is at most as high as an aluminum content of the first cladding layer. The aluminum content of the semiconductor layers can influence, among other things, the size of the bandgap of the material. An equally high or higher aluminum content in the first cladding layer results in particular in a large overlap area of an optical mode propagating in the semiconductor body with an electrically pumped section of the active region. In other words, an equally high or higher aluminum content in the first cladding layer advantageously results in a particularly large optical fill factor for an optical mode propagating in the semiconductor body.

According to at least one embodiment of the optoelectronic semiconductor component, an aluminum content of the first cladding layer is at most as high as an aluminum content of the first spacer layer. Among other things, the aluminum content of the semiconductor layers can influence the size of the bandgap of the material. An equally high or higher aluminum content in the first spacer layer results in particular in a shift of a mode propagating in the semiconductor body during operation to the less absorbing n-conducting region. Consequently, internal absorption losses can be further reduced. In other words, an equally high or higher aluminum content in the first spacer layer advantageously results in a particularly low optical absorption for an optical mode propagating in the semiconductor body.

According to at least one embodiment of the optoelectronic semiconductor component, the doping region comprises an electron blocking layer, a ramp region and a first contact layer formed with a semiconductor material selected from the following group: GaN, AlGaN, InGaN, AlInGaN. In particular, the electron blocking layer increases the confinement time of charge carriers in the active region. Preferably, the electron blocking layer is formed with an AlGaN, since a relatively high bandgap is advantageous for the function of the electron blocking layer. The ramp region comprises a region in which the electrical bandgap is varied. In particular, the ramp region has a varying aluminum content to generate a ramp of the bandgap. The ramp region improves an electrical injection efficiency, thereby helping to reduce a voltage drop in the p-conducting region. The first contact layer is preferably formed with GaN, as a relatively small bandgap is advantageous to establish a good electrical contact to further subsequent layers. In particular, the ramp region is located between the electron blocking layer and the first contact layer. Preferably, the electron blocking layer is arranged on the side of the doping region facing the active region. In particular, the spacer region extends between the electron blocking layer and the active region of the semiconductor body.

According to at least one embodiment of the optoelectronic semiconductor component, the first spacer layer comprises a semiconductor material having the general formula

AlₓIn_{y}Ga_{1-x-y}N and the electron blocking layer comprises a semiconductor material having the general formula Al_{q}In_{z}Ga_{1-q-z}N, where (q−z)−(x−y)≥0.12, preferably (q−z)−(x−y)≥0.15 and particularly preferably (q−z)−(x−y)≥0.2.

In other words, the electron blocking layer has an aluminum content that is 12 percentage points, preferably 15 percentage points and particularly preferably 20 percentage points higher than the first spacer layer. This advantageously results in an increased bandgap in the electron blocking layer relative to the first spacer layer. For example, the electron blocking layer contains indium in order to reduce mechanical stress in the electron blocking layer relative to the first contact layer. Furthermore, an increased indium content in the first spacer layer can reduce a bandgap in the first spacer layer. By combining a different aluminum content and a different indium content, a jump in the bandgap between the electron blocking layer and the first spacer layer can be induced particularly easily.

If no indium is to be used, the entire bandgap jump must be caused by a different aluminum content. Consequently, in particular q−x≥0.12, preferably q−x≥0.15 and particularly preferably q−x≥0.2.

According to at least one embodiment of the optoelectronic semiconductor component, the ramp region has a decreasing aluminum content in the direction away from the side of the electron blocking layer facing the active region. A decreasing aluminum content can generate a decreasing bandgap in the direction away from the electron blocking layer. A decreasing bandgap over a ramp or multiple steps can advantageously generate a higher injection efficiency.

According to at least one embodiment of the optoelectronic semiconductor component, the ramp region has a starting point at an interface to the electron blocking layer and an end point at an interface to the first contact layer, wherein the aluminum content at the starting point corresponds at most to the aluminum content of the electron blocking layer, preferably less than three quarters of the aluminum content of the electron blocking layer, further preferably less than two thirds of the aluminum content of the electron blocking layer and particularly preferably less than half of the aluminum content of the electron blocking layer. A particularly high injection efficiency and sufficient function of the electron blocking layer can be achieved by selecting the starting point in this way.

According to at least one embodiment of the optoelectronic semiconductor component, the ramp region has a starting point at an interface to the electron blocking layer and an end point at an interface to the first contact layer, wherein the aluminum content at the end point corresponds to at least the aluminum content of the first contact layer. The aluminum content of the ramp region at the end point can also be higher than the aluminum content of the first contact layer. Consequently, there is a step in the curve of the aluminum content at the interface between the ramp region and the first contact layer.

According to at least one embodiment of the optoelectronic semiconductor component, the first spacer layer has a semiconductor material with the general formula AlₓIn_{y}Ga_{1-x-y}N, where 0≤x≤0.15, preferably 0.01≤x≤0.1, particularly preferably 0.03≤x≤0.08 and 0≤y≤0.01, preferably 0≤y≤0.05. In particular, the first spacer layer consists of the material according to the above formula.

According to at least one embodiment of the optoelectronic semiconductor component, the first waveguide is formed with a material according to the following composition: InₙGa₁₋ₙN, and the third spacer layer is formed with a material according to the following composition: InₘGa₁₋ₘN, wherein the following relationship applies to the difference in indium content: |n−m|≥0.003, preferably |n−m|≥0.008 and particularly preferably |n-m|≥0.01. In other words, an indium content of the third spacer layer differs from an indium content of the first waveguide by at least 0.3 percentage points, preferably by at least 0.8 percentage points and particularly preferably by at least 1 percentage point.

Advantageously, the indium content in the first waveguide is higher than the indium content in the third spacer layer. A difference in the indium content can increase the injection efficiency of charge carriers into the active region. In addition, fabrication of the semiconductor component may be facilitated by the distinctness of the first waveguide and the third spacer layer. Preferably, the first waveguide and/or the first cladding layer contain between 0 and 10%, more preferably between 0.5 and 6% indium. For example, the sum formula of the first waveguide and the third spacer layer is 0<n≤0.1, preferably 0.005≤n≤0.06 and 0≤m≤0.1, preferably 0.005≤m≤0.06.

According to at least one embodiment of the optoelectronic semiconductor component, a ridge edge extends from the second region at least completely through the active region, preferably at least into the first cladding layer, particularly preferably completely through the first cladding layer. For example, the ridge edge extends into the first waveguide, in particular completely through the first waveguide. In particular, the ridge edge extends into the second waveguide, in particular completely through the second waveguide. A ridge edge is, for example, a step-shaped cut-out on a side surface of the semiconductor body. The ridge edge can delimit a lateral extension of the semiconductor body. Consequently, a lateral extension of an optical mode in the semiconductor body can be delimited by the ridge edge. The lateral direction extends transversely, in particular perpendicular to the stacking direction of the semiconductor body.

According to at least one embodiment of the optoelectronic semiconductor component, a vertical extension of the doping region is less than 150 nm, preferably less than 100 nm, particularly preferably less than 50 nm. A particularly small vertical extension of the doping region contributes to an advantageously low voltage drop.

According to at least one embodiment of the optoelectronic semiconductor component, the first spacer layer has a vertical extension of between 1 nm and 2000 nm, preferably between 40 nm and 800 nm and particularly preferably between 100 nm and 500 nm. A particularly large vertical extension of the first spacer layer can advantageously reduce optical absorption in the semiconductor body. Too large a vertical extension of the first spacer layer could disadvantageously increase a voltage drop in the p-conducting region.

According to at least one embodiment of the optoelectronic semiconductor component, an electrode is arranged downstream of the doping region on a side facing away from the active region, the electrode being formed with a transparent conductive oxide. For example, the electrode is formed with an indium tin oxide. In particular, a vertical extension of the electrode is between 100 nm and 300 nm, preferably between 150 nm and 250 nm. The electrode can influence a distribution of an optical mode in the semiconductor body, whereby a particularly high overlap of the optical mode with the electrically excited region of the active region can be generated.

According to at least one embodiment of the optoelectronic semiconductor component, a tunnel diode region is arranged on a side of the p-doped region facing away from the active region. In particular, the tunnel diode region has a high dopant concentration of p- and n-dopants. Preferably, the tunnel diode region has an n-dopant concentration of more than 10¹⁹ cm⁻³. Further preferably, the tunnel diode region has a p-dopant concentration of more than 5*10¹⁹ cm⁻³, preferably more than 10²⁰ cm⁻³. In particular, the tunnel diode region has a low thickness. A thickness is considered here and in the following as an extension in the vertical direction. For example, the tunnel diode region has a vertical extension of at most 50 nm, preferably of at most 30 nm and particularly preferably of at most 5 nm. Due to the high dopant concentration and the small vertical extension of the tunnel diode region, such a narrow space charge zone can be formed that a transport of charge carriers by means of quantum mechanical tunnel effects is made possible. Advantageously, a p-doped region with a low electrical resistance can be electrically conductively connected to an n-doped region.

According to at least one embodiment of the optoelectronic semiconductor component, a second cladding layer is arranged on a side of the tunnel diode region facing away from the active region. Preferably, the second cladding layer is n-doped. The second cladding layer is formed with AlGaN, for example. In particular, the second cladding layer has the same composition as the first cladding layer. The second cladding layer has a vertical extension of between 1 nm and 2 μm, preferably between 50 nm and 800 nm and particularly preferably between 150 nm and 500 nm.

According to at least one embodiment of the optoelectronic semiconductor component, a second contact layer is arranged on a side of the tunnel diode region facing away from the active region. The second contact layer is preferably formed with GaN, as a relatively small bandgap is advantageous in order to establish good electrical contact with other subsequent layers. The second contact layer is particularly n-doped. Compared to a p-doped first contact layer, the second contact layer has an advantageously lower electrical resistance.

According to at least one embodiment of the optoelectronic semiconductor component, a plurality of semiconductor bodies is arranged one above the other, with a tunnel diode region being arranged between two semiconductor bodies in each case. By means of the tunnel diode region, it is possible to electrically connect a p-doped region of a first semiconductor body with an n-doped region of a second semiconductor body. Stacking several semiconductor bodies can result in a very compact light source with a particularly high output power and slope.

According to at least one embodiment of the optoelectronic semiconductor component, a bandgap within the first spacer layer increases starting from an interface facing the active region. In other words, an electrical bandgap increases within the first spacer layer with an increasing distance from the active region. The increase in the electrical bandgap is caused in particular by an increase in a proportion of aluminum in the first spacer layer. Preferably, a proportion of aluminum in the first spacer layer increases with increasing distance from the active region. The electrical bandgap changes along a vertical extension of the first spacer layer, for example continuously or in steps. A bandgap formed in this way within the first spacer layer advantageously results in a lower charge carrier density within the first spacer layer, which advantageously reduces the probability of non-radiative recombination processes.

According to at least one embodiment of the optoelectronic semiconductor component, a bandgap within the second spacer layer increases starting from an interface facing the active region. In other words, an electrical bandgap increases within the second spacer layer with an increasing distance from the active region. The increase in the electrical bandgap is caused in particular by a decrease in a proportion of indium in the second spacer layer. Preferably, a proportion of indium in the second spacer layer decreases with increasing distance from the active region. The electrical bandgap changes along a vertical extension of the second spacer layer, for example continuously or in steps. A bandgap formed in this way within the second spacer layer advantageously results in a lower charge carrier density within the second spacer layer, which advantageously reduces the probability of non-radiative recombination processes.

A method for producing an optoelectronic semiconductor component is further disclosed. The optoelectronic semiconductor component can be produced in particular by means of a method described herein. That is, all features disclosed in connection with the method for producing an optoelectronic semiconductor component are also disclosed for the optoelectronic semiconductor component and vice versa.

According to at least one embodiment, the method for producing an optoelectronic semiconductor component comprises the following steps:
providing a p-doped doping region and at least partially providing a tunnel diode region,
performing a temperature step at a temperature above 300° C., preferably above 450° C. and particularly preferably above 600° C. to activate the p-doping.

The p-doped doping region is produced using molecular beam epitaxy (MBE for short), for example. An MBE method can be used in particular because there is no hydrogen in the reactor to passivate the p-dopant, for example magnesium. The temperature step is preferably carried out prior to the growth of an n-doped region. The p-doping is activated, for example, by removing hydrogen. In particular, the p-doping is formed with magnesium.

According to at least one embodiment of the method for producing an optoelectronic semiconductor component, the temperature step is carried out with the addition of oxygen. Advantageously, an addition of oxygen facilitates a removal of hydrogen from the optoelectronic semiconductor component.

According to at least one embodiment of the method for producing an optoelectronic semiconductor component, the p-doped region is at least partially exposed by etching. Preferably, the etching does not completely penetrate the tunnel diode region. At least partial exposure allows hydrogen to diffuse out of the p-doped layers. For example, at least partial exposure of the p-doped layers is achieved by ridge etching.

An optoelectronic semiconductor component described herein is particularly suitable for use as a light source with high output power, for example for material processing, projection applications, general lighting or automotive applications, for example in headlights or a head-up display.

### BRIEF DESCRIPTION OF THE DRAWINGS

Further advantages and advantageous configurations and further embodiments of the optoelectronic semiconductor component result from the following exemplary embodiments shown in connection with the figures.

FIG. 1 shows a schematic sectional view of an optoelectronic semiconductor component described herein according to a first exemplary embodiment;

FIG. 2 shows a theoretical characteristic curve of an optoelectronic semiconductor component described herein according to the first exemplary embodiment;

FIG. 3 shows a theoretical efficiency characteristic of an optoelectronic semiconductor component described herein according to the first exemplary embodiment;

FIG. 4 shows a curve of a bandgap and an optical intensity of an optoelectronic semiconductor component described herein according to the first exemplary embodiment;

FIGS. 5A-5E each show a curve of an aluminum content in a doping region of an optoelectronic semiconductor component described herein according to the first exemplary embodiment;

FIGS. 6A-6D each show a curve of a bandgap in a first spacer layer of an optoelectronic semiconductor component described herein according to the first exemplary embodiment;

FIG. 7 shows a schematic sectional view of an optoelectronic semiconductor component described herein according to a second exemplary embodiment;

FIG. 8 shows a curve of a bandgap in a first spacer layer relative to a first cladding layer of an optoelectronic semiconductor component described herein according to the first exemplary embodiment;

FIG. 9 shows a curve of a bandgap and an optical intensity of an optoelectronic semiconductor component described herein according to the first exemplary embodiment;

FIG. 10 shows a curve of a bandgap and an optical intensity of an optoelectronic semiconductor component described herein according to a third exemplary embodiment;

FIG. 11 shows a curve of a bandgap and an optical intensity of an optoelectronic semiconductor component described herein according to the first exemplary embodiment;

FIG. 12 shows a schematic sectional view of an optoelectronic semiconductor component described herein according to a fourth exemplary embodiment;

FIG. 13 shows a schematic sectional view of an optoelectronic semiconductor component described herein according to a fifth exemplary embodiment;

FIG. 14 shows a schematic sectional view of an optoelectronic semiconductor component described herein according to a sixth exemplary embodiment;

FIG. 15 shows a schematic sectional view of an optoelectronic semiconductor component described herein according to a seventh embodiment;

FIG. 16 shows a schematic sectional view of an optoelectronic semiconductor component described herein according to an eighth exemplary embodiment;

FIG. 17 shows a schematic sectional view of an optoelectronic semiconductor component described herein according to a ninth exemplary embodiment;

FIG. 18 shows a curve of a bandgap of an optoelectronic semiconductor component described herein according to a tenth exemplary embodiment; and

FIG. 19 shows a curve of a bandgap of an optoelectronic semiconductor component described herein according to an eleventh exemplary embodiment.

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

### DETAILED DESCRIPTION OF ILLUSTRATIVE EMBODIMENTS

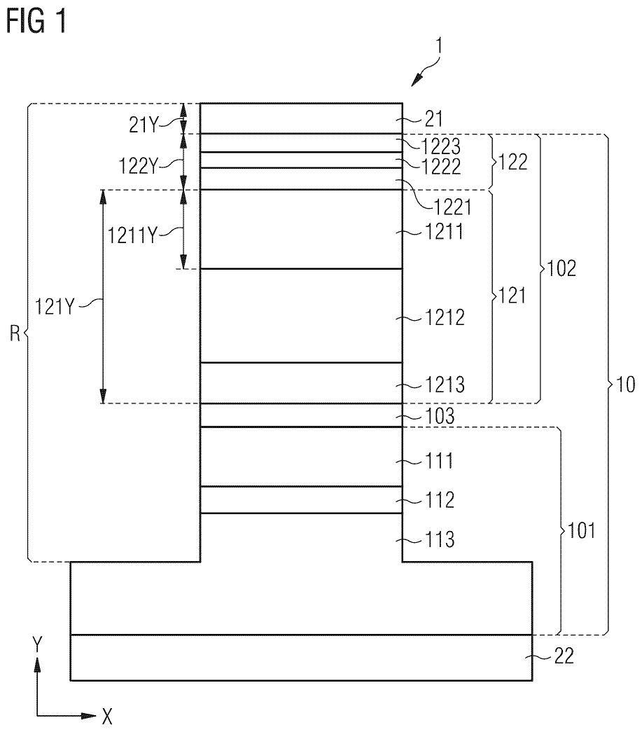

FIG. 1 shows a schematic sectional view of an optoelectronic semiconductor component 1 described herein according to a first exemplary embodiment. The semiconductor component 1 comprises a semiconductor body 10, which is formed as a monolithically grown layer stack. The semiconductor body 10 comprises an n-conducting region 101, a p-conducting region 102 and an active region 103 configured to emit electromagnetic radiation.

The semiconductor body 10 is formed with a III/V compound semiconductor material, in particular a nitride compound semiconductor material. A III/V compound semiconductor material has at least one element from the third main group, such as B, Al, Ga, In, and one element from the fifth main group, such as N, P, As. In particular, the term “III/V compound semiconductor material” comprises the group of binary, ternary or quaternary compounds which contain at least one element from the third main group and at least one element from the fifth main group, for example nitride and phosphide compound semiconductors. Such a binary, ternary or quaternary compound may also have, for example, one or more dopants and additional components.

The p-conducting region 102 comprises at least one semiconductor layer that is p-doped, and the n-conducting region 101 comprises at least one semiconductor layer that is n-doped. The active region 103 may comprise a double heterostructure, a single quantum well structure or a multi-quantum well structure. In operation, the active region 103 is provided to emit electromagnetic radiation and is disposed between the n-conducting region 101 and the p-conducting region 102.

The p-conducting region 102 has a spacer region 121 and a p-doped doping region 122. The spacer region 121 is arranged between the doping region 122 and the active region 103. The spacer region 121 comprises an unintentionally doped semiconductor material. In other words, no dopant atoms are intentionally introduced into the semiconductor material of the spacer region 121.

The spacer region 121 comprises a first spacer layer 1211 comprising aluminum. The spacer layer 1211 is formed, for example, with a semiconductor material comprising aluminum. For example, the first spacer layer 1211 is formed with AlGaN. In particular, the first spacer layer 1211 is formed with a material having the following formula AlₓIn_{y}Ga_{1-x-y}N, where 0≤y≤0.05. Advantageously, a semiconductor layer formed with aluminum can have a particularly high bandgap and thus exhibit particularly good waveguiding for electromagnetic radiation generated in the active region 103 during operation.

A vertical extension 122Y of the doping region corresponds to at most one third, preferably at most one fifth, particularly preferably at most one eighth of a vertical extension 121Y of the spacer region 121. Here and in the following, the vertical direction Y is considered to be a direction parallel to a stacking direction of the semiconductor body 10. The stacking direction is the direction in which the various semiconductor regions of the semiconductor body 10 are stacked or grown on top of each other. A small vertical extension 122Y of the doping region 122 relative to the spacer region 121 can advantageously result in a particularly low optical absorption in the semiconductor component 1. The spacer region 121 extends from the active region 103 to the electron blocking layer 1221 of the doping region 122.

The first spacer layer 1211 has a vertical extension 1211Y between 1 nm and 2000 nm, preferably between 40 nm and 800 nm and particularly preferably between 100 nm and 500 nm. A particularly large vertical extension 1211Y of the first spacer layer 1211 can advantageously reduce optical absorption in the semiconductor body 10. Too large a vertical extension 1211Y of the first spacer layer 1211 could disadvantageously increase a voltage drop in the p-conducting region 102, and therefore there is an optimal range.

A vertical extension 122Y of the doping region is less than 150 nm, preferably less than 100 nm, particularly preferably less than 50 nm. A particularly small vertical extension 122Y of the doping region 122 contributes to an advantageously low voltage drop.

The spacer region 121 further comprises a second spacer layer 1212 and a third spacer layer 1213. The second and third spacer layers 1212, 1213 are formed with a nominally undoped semiconductor material. Preferably, for electromagnetic radiation generated in the active region during operation, a refractive index of the second and third spacer layers 1212, 1213 is higher than a refractive index of the first spacer layer 1211. Advantageously, this results in better guidance of the electromagnetic radiation in the vertical direction Y.

The n-conducting region 101 comprises a first waveguide 111, a second waveguide 112 and a first cladding layer 113. The first and second waveguides 111, 112 are arranged between the first cladding layer 113 and the active region 103. Advantageously, the first and second waveguides 111, 112 have a higher refractive index for electromagnetic radiation generated in the active region 103 during operation than the first cladding layer 113.

The first cladding layer 113 has a higher n-doping than the first waveguide 111 and the second waveguide 112. A relatively low doping of the first and second waveguides 111, 112 causes, among other things, a reduction in the internal absorption losses of the semiconductor component 1.

The doping region 122 of the p-conducting region 102 includes an electron blocking layer 1221, a ramp region 1222, and a first contact layer 1223. The layers of the doping region 122 are formed with a semiconductor material selected from the following group: GaN, AlGaN, InGaN, AlInGaN. In particular, the electron blocking layer 1221 increases a confinement time of charge carriers in the active region 103. Preferably, the electron blocking layer 1221 is formed with an AlGaN, as a relatively high bandgap is advantageous for the function of the electron blocking layer 1221. The ramp region 1222 comprises a region in which the electrical bandgap is varied. In particular, the ramp region 1222 has a varying aluminum content to generate a ramp of the bandgap. The ramp region 1222 improves an electrical injection efficiency, thereby helping to reduce a voltage drop in the p-conducting region 102. The first contact layer 1223 is preferably formed with GaN, as a relatively small bandgap is advantageous to establish a good electrical contact to further subsequent layers. The ramp region 1222 is arranged between the electron blocking layer 1221 and the first contact layer 1223. The electron blocking layer 1221 is arranged on the side of the doping region 122 facing the active region 103. The spacer region 121 extends between the electron blocking layer 1221 and the active region 103.

An electrode 21 is arranged downstream of the first contact layer 1223. The electrode 21 is formed with a transparent conductive oxide. For example, the electrode 21 is formed with indium tin oxide. In particular, a vertical extension 21Y of the electrode 21 is between 100 nm and 300 nm, preferably between 150 nm and 250 nm. The electrode 21 can influence a distribution of an optical mode in the semiconductor body 10, whereby a particularly high overlap of the optical mode with the electrically excited region of the active region 103 can be generated.

A ridge edge R is structured in the semiconductor body. The ridge edge R extends from the electrode 21 at least into the first cladding layer 113 or through the first cladding layer 113. The ridge edge R is a step-shaped cut-out on a side surface of the semiconductor body 10. The ridge edge R delimiting a lateral extension of the semiconductor body 10 along the lateral direction X. The lateral direction X extends transversely, in particular perpendicular to the stacking direction of the semiconductor body 10. For example, the active region 103 has a lateral extent of from 5 μm to 100 μm, preferably from 15 μm to 100 μm and particularly preferably from 30 to 60 μm.

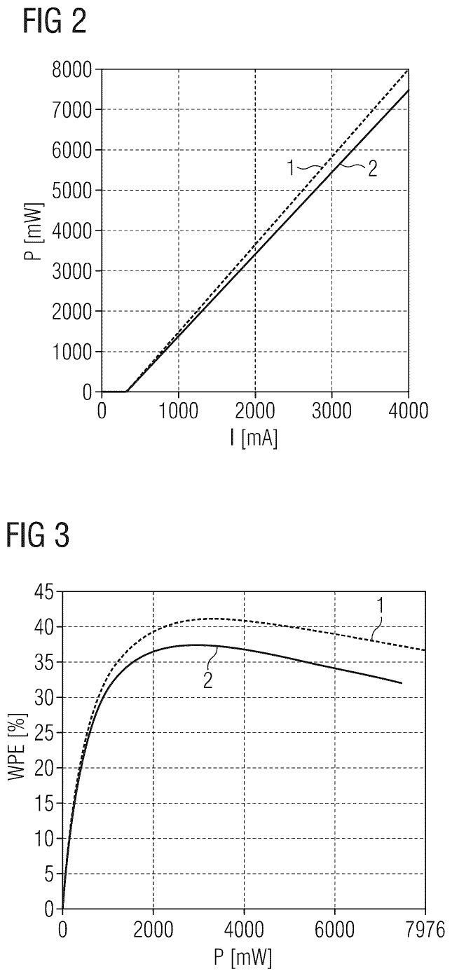

FIG. 2 shows a theoretical characteristic curve of an optoelectronic semiconductor component 1 described herein according to the first exemplary embodiment. The characteristic curve shows an optical output power P in mW as a function of an operating current I in mA. The output power of an optoelectronic semiconductor component 1 according to the first exemplary embodiment is advantageously higher than the output power of an optoelectronic semiconductor component 2 according to an exemplary embodiment from the prior art.

FIG. 3 shows a theoretical efficiency characteristic of an optoelectronic semiconductor component 1 described here according to the first exemplary embodiment. The characteristic curve shows a wall-plug efficiency (WPE) in percent as a function of an optical output power P in mW. The wall-plug efficiency describes the energy conversion efficiency with which the system converts electrical power into optical power. It is defined as the ratio of the radiant flux (i.e. the total optical output power) to the electrical input power.

The socket efficiency of an optoelectronic semiconductor component 1 according to the first exemplary embodiment is advantageously higher than the socket efficiency of an optoelectronic semiconductor component 2 according to an exemplary embodiment from the prior art. The socket efficiency of the optoelectronic semiconductor component 1 according to the first exemplary embodiment reaches a maximum value of over 41% at an optical output power of over 3000 mW.

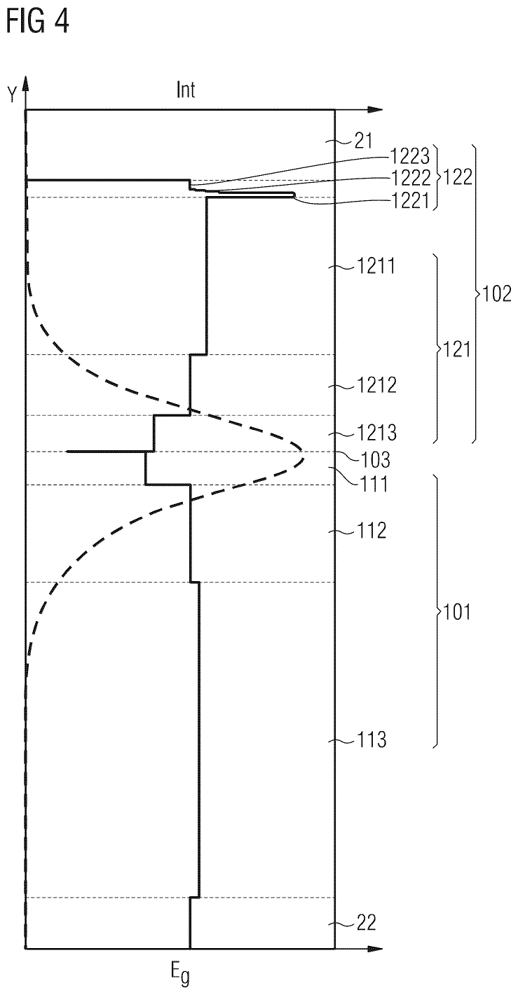

FIG. 4 shows a curve of a bandgap E_{g} and an optical intensity Int of an optoelectronic semiconductor component 1 described here according to the first exemplary embodiment along the vertical direction Y. The curve of the intensity Int is shown here and in the following figures with a dashed line. It can be seen that the optical intensity Int has a global maximum near the active region 103. The optical intensity Int decreases steadily in the direction of the electrode 21 and is already almost zero in the doping region 122. Consequently, the electromagnetic radiation emitted in the active region 103 during operation is almost completely shielded by the strongly absorbing doping region 122 of the p-conducting region 102.

The curve of the bandgap E_{g} is shown here and in the following figures with a continuous line and has a minimum in the region of the active region 103. The bandgap E_{g} has a global maximum in the electron blocking layer 1221 in the doping region 122. Starting from the active region 103 up to the interfaces with the electrode 21 and the substrate 22, the bandgap E_{g} increases in several steps.

In the n-doped layers of the n-conducting region 101 near the active region 103, a dopant concentration is lowered compared to the first cladding layer 113. For example, an n-dopant concentration in the first waveguide 111 and the second waveguide 112 is lower than an n-dopant concentration in the first cladding layer 113 by at least a factor of 2, preferably by at least a factor of 3. In this way, optical absorption in the n-conducting region 102 can be reduced.

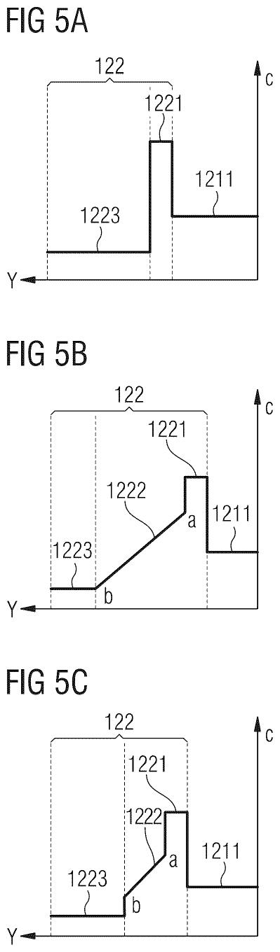

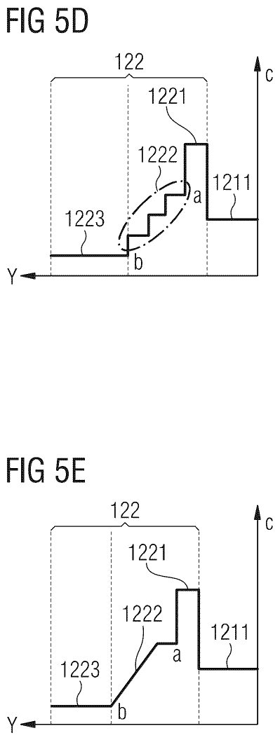

FIGS. 5A to 5E each show a curve of an aluminum content c in a doping region 122 of an optoelectronic semiconductor component 1 described herein according to the first exemplary embodiment. The aluminum content of the semiconductor layers in the doping region 122 influences the bandgap of the doping region 122. An increasing aluminum content causes an increasing bandgap and vice versa. FIGS. 5A to 5E each show the aluminum content c as a function of the vertical direction Y.

The first spacer layer 1211 has a semiconductor material with the general formula AlₓIn_{y}Ga_{1-x-y}N and the electron blocking layer 1221 has a semiconductor material with the general formula Al_{q}In_{z}Ga_{1-q-z}N, where (q−z)−(x−y)≥0.12, preferably (q−z)−(x−y)≥0.15 and particularly preferably (q−z)−(x−y)≥0.2.

In other words, the electron blocking layer 1221 has a higher aluminum content than the first spacer layer 1211 by 12 percentage points, preferably by 15 percentage points and particularly preferably by 20 percentage points. This advantageously results in an increased bandgap in the electron blocking layer 1221 relative to the first spacer layer 1211. For example, the electron blocking layer 1221 includes indium to reduce a mechanical strain of the electron blocking layer 1221 relative to the first contact layer 1223. Furthermore, an indium content can reduce a bandgap in the first spacer layer 1211. By combining a different aluminum content and a different indium content, a jump in the bandgap between the electron blocking layer 1221 and the first spacer layer 1211 can be induced particularly easily.

In the event that no indium is to be used in the first spacer layer 1211, the entire bandgap jump must be caused by a different aluminum content. Consequently, q−x≥0.12 applies in particular, preferably q−x≥0.15 and particularly preferably, q−x≥0.2.

FIG. 5A shows a first curve of an aluminum content in the doping region 122. The electron blocking layer 1221 is disposed between a first contact layer 1223 and a first spacer layer 1211. The aluminum content of the electron blocking layer 1221 is at least 12 percentage points higher than the aluminum content of the first spacer layer 1211. The first contact layer 1223 preferably comprises no aluminum. Consequently, the aluminum content of the first contact layer 1223 is zero.

FIG. 5B shows a second curve of an aluminum content in the doping region 122. The second curve essentially corresponds to the first curve shown in FIG. 5A. In contrast to the first curve, a ramp region 1222 is arranged between the electron blocking layer 1222 and the first contact layer 1223. The ramp region 1222 describes a region in which an aluminum portion in a semiconductor region is varied along the vertical direction Y.

The ramp region 1222 comprises a starting point 1222a at an interface with the electron blocking layer 1221 and an end point 1222b at an interface with the first contact layer 1223. The aluminum content at the starting point 1222a corresponds at most to the aluminum content of the electron blocking layer 1221.

In the curve shown in FIG. 5B, the aluminum content at the starting point 1222a corresponds to less than three-quarters of the aluminum content of the electron blocking layer 1221. By selecting the starting point 1222a in this way, a particularly high injection efficiency and a sufficient function of the electron blocking layer 1221 can be achieved.

In the ramp region 1222, the aluminum content decreases steadily from the starting point 1222a to the end point 1222b. At the end point 1222b, the aluminum content of the ramp region 1222 is equal to the aluminum content of the first contact layer 1223.

FIG. 5C shows a third curve of an aluminum content in the doping region 122. The third curve essentially corresponds to the second curve shown in FIG. 5B. In contrast to the second curve, the aluminum content at the starting point 1222a corresponds to less than two thirds of the aluminum content of the electron blocking layer 1221. By selecting the starting point 1222a in this way, a particularly high injection efficiency and sufficient function of the electron blocking layer 1221 can be achieved.

In the ramp region 1222, the aluminum content decreases steadily from the starting point 1222a to the end point 1222b. At the end point 1222b, the aluminum content of the ramp region 1222 is higher than the aluminum content of the first contact layer 1223. Consequently, a step remains in the curve of the aluminum content between the ramp region 1222 and the first contact layer 1223.

FIG. 5D shows a fourth curve of an aluminum content in the doping region 122. The fourth curve essentially corresponds to the second curve shown in FIG. 5B. In contrast to the second curve, the aluminum content at the starting point 1222a corresponds to less than half of the aluminum content of the electron blocking layer 1221. By selecting the starting point 1222a in this way, a particularly high injection efficiency and a sufficient function of the electron blocking layer 1221 can be achieved.

In the ramp region 1222, the aluminum content decreases in a plurality of steps from the starting point 1222a to the end point 1222b. At the end point 1222b, the aluminum content of the ramp region 1222 is higher than the aluminum content of the first contact layer 1223. Consequently, a step remains in the curve of the aluminum content between the ramp region 1222 and the first contact layer 1223. A step-shaped ramp region 1222 is advantageously particularly easy to manufacture.

FIG. 5E shows a fifth curve of an aluminum content in the doping region 122. The fifth curve essentially corresponds to the second curve shown in FIG. 5B. In contrast to the second curve, the aluminum content at the starting point 1222a corresponds to less than half of the aluminum content of the electron blocking layer 1221. By selecting the starting point 1222a in this way, a particularly high injection efficiency and a sufficient function of the electron blocking layer 1221 can be achieved.

In the ramp region 1222, the aluminum content initially remains constant from the starting point 1222a to the end point 1222b and then decreases steadily. At the end point 1222b, the aluminum content of the ramp region 1222 is equal to the aluminum content of the first contact layer 1223.

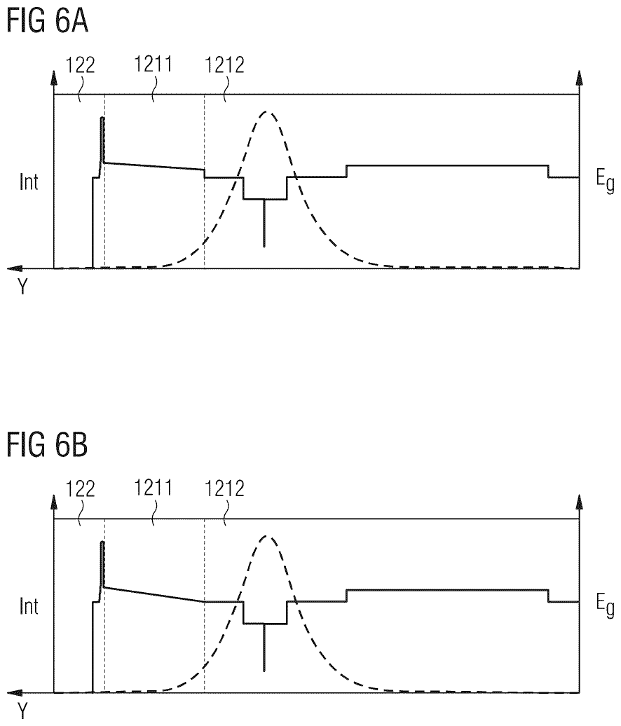

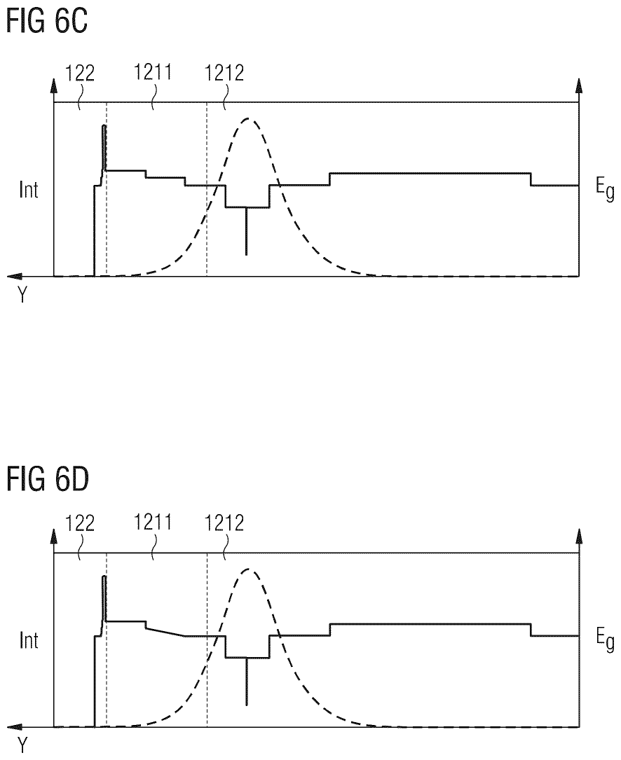

FIGS. 6A to 6D each show a curve of a bandgap in a first spacer layer 1211 of an optoelectronic semiconductor component 1 described herein according to the first exemplary embodiment.

FIG. 6A shows a first curve of a bandgap that has a step at an interface with the second spacer layer 1212 and then steadily increases to the interface with the doping region 122.

FIG. 6B shows a second curve of a bandgap that increases steadily from the interface with the second spacer layer 1212 to the interface with the doping region 122. A particularly steady curve of the bandgap without steps is particularly advantageous for a high injection efficiency.

FIG. 6C shows a third curve of a bandgap that increases in a plurality of steps from the interface with the second spacer layer 1212 to the interface with the doping region 122. Such a curve is particularly easy to produce, for example, by using a multilayer first spacer layer 1211. For example, the first spacer layer 1211 comprises three or more layers of semiconductor material, each with a different bandgap.

FIG. 6D shows a fourth curve of a bandgap that increases starting from the interface with the second spacer layer 1212 in a combination of a step and a partially continuous curve up to the interface with the doping region 122.

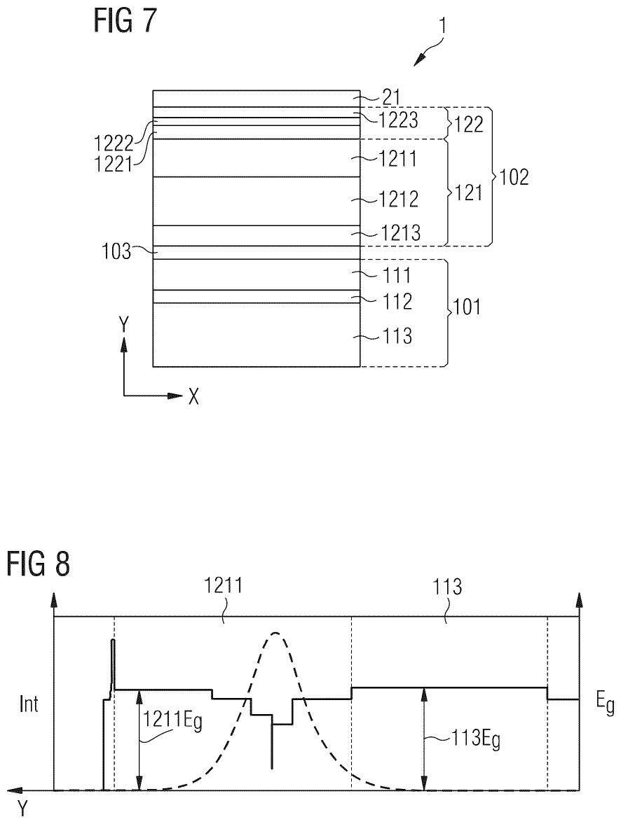

FIG. 7 shows a schematic sectional view of an optoelectronic semiconductor component 1 described herein according to a second exemplary embodiment. The second exemplary embodiment essentially corresponds to the first exemplary embodiment shown in FIG. 1. In contrast to the first exemplary embodiment, no ridge edge R is provided in the second exemplary embodiment. A lateral extension of the semiconductor body 10 is thus increased. Advantageously, broad stripe lasers can be produced in this way. For example, the active region 103 has a lateral extent of at least 50 μm, preferably of at least 100 μm and particularly preferably of at least 150 μm.

Further, the first waveguide 111 is formed with a material according to the following composition: InₙGa₁₋ₙN, and the third spacer layer 1213 is formed with a material according to the following composition: InₘGa₁₋ₘN, wherein the following relationship applies to the difference in indium content:

|n−m|≥0.003, preferably |n−m|≥0.008 and particularly preferably |n−m|≥0.01. In other words, an indium content of the third spacer layer 1213 differs from an indium content of the first waveguide 111 by at least 0.3 percentage points, preferably by at least 0.8 percentage points and particularly preferably by at least 1 percentage point.

Advantageously, the indium content in the first waveguide 111 is higher than the indium content in the third spacer layer 1213. For example, the first waveguide 111 has an indium content of 5% and the third spacer layer 1213 has an indium content of 4%. A difference in the indium content may increase an injection efficiency of charge carriers into the active region 103. In addition, a fabrication of the semiconductor component 1 may be facilitated by the distinguishability of the first waveguide 111 and the third spacer layer 1213.

Preferably, the first waveguide 111 and/or the third spacer layer 1213 contain between 0% and 10%, preferably between 0.5% and 6% indium. For example, the formula of the first waveguide 111 and the third spacer layer 1213 corresponds to the limits of 0<n≤0.1, preferably 0.005≤n≤0.06 and 0≤m≤0.1, preferably 0.005≤m≤0.06.

FIG. 8 shows a curve of a bandgap in a first spacer layer 1211 relative to a first cladding layer 113 of an optoelectronic semiconductor component 1 described herein according to the first exemplary embodiment. The bandgap 1211E_{g} of the first spacer region 1211 is at most as high as the bandgap 113E_{g} of the first cladding layer 113. This is possible, for example, by adjusting the aluminum content.

An aluminum content of the first spacer layer 1211 is at most as high as an aluminum content of the first cladding layer 113. An equally high or higher aluminum content in the first cladding layer 113 results in particular in a large overlap area of an optical mode propagating in the semiconductor body 10 with an electrically pumped section of the active region 103. Consequently, an advantageously low laser threshold current can be achieved.

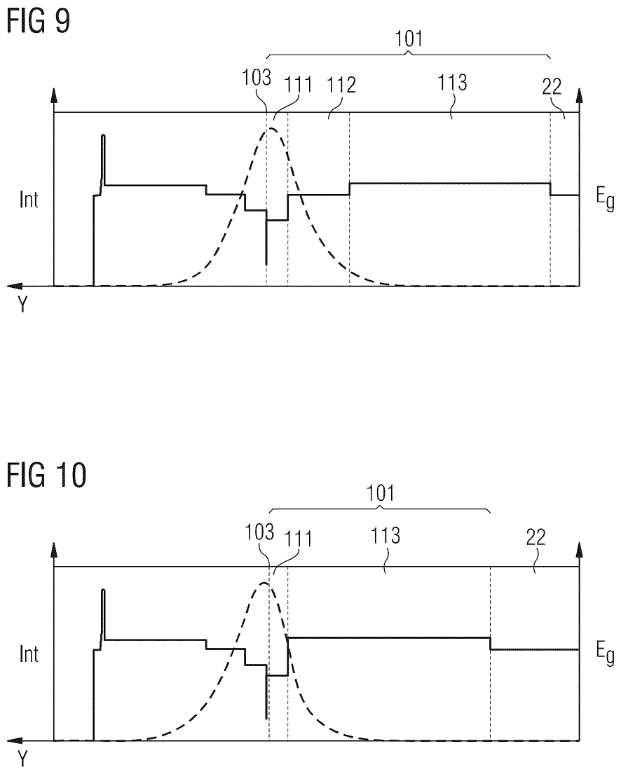

FIG. 9 shows a curve of a bandgap and an optical intensity of an optoelectronic semiconductor component 1 described herein according to the first exemplary embodiment.

Peak doping regions are preferably provided at an interface between the first waveguide 111 and the second waveguide 112 and/or at an interface of the second waveguide 112 to the first cladding layer 113.

Peak doping regions are locally delimiting increases in a dopant concentration. In particular, a concentration of an n-dopant at the interfaces between the first waveguide 111 and the second waveguide 112 and between the second waveguide 112 and the first cladding layer 113 is increased compared to the immediately adjacent region. For example, a doping of the peak doping region increases in the direction away from the active region 103 by at least a first percentage value and decreases again by at least a second percentage value, wherein the first and the second percentage value are greater than 10% of a maximum doping of the peak doping region. Advantageously, a voltage drop in the n-conducting region 101 can thus be reduced or avoided.

Advantageously, the curve of the bandgap E_{G} in a stacking direction of the semiconductor body 10 is in each case constant within the regions in the n-conducting region 101. In other words, the bandgap E_{G} within the first waveguide 111, the second waveguide 112 and the first cladding layer 113 are in each case constant along their vertical extension.

FIG. 10 shows a curve of a bandgap and an optical intensity of an optoelectronic semiconductor component 1 described herein according to a third exemplary embodiment. The third exemplary embodiment essentially corresponds to the first exemplary embodiment shown in FIG. 9. In contrast to the first exemplary embodiment, the first waveguide 111 is directly adjacent to the first cladding layer 113. This eliminates the need for a second waveguide 112.

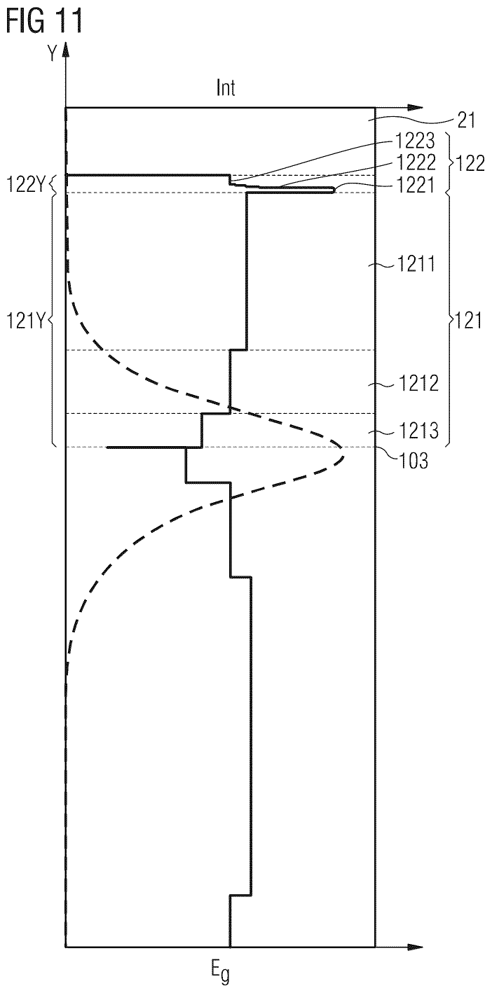

FIG. 11 shows a curve of a bandgap and an optical intensity of an optoelectronic semiconductor component described herein according to the first exemplary embodiment 1. In FIG. 11, it can be seen in particular that a vertical extension 122Y of the doping region 122 is less than a vertical extension 121Y of the spacer region 121. The vertical extension 122Y of the doping region 122 corresponds to at most one third, preferably at most one fifth, particularly preferably at most one eighth of the vertical extension 121Y of the spacer region 121Y. This enables particularly good shielding of the electromagnetic radiation from the absorbing doping region 122.

The vertical extension 122Y of the doping region 122 is less than 150 nm, preferably less than 100 nm, particularly preferably less than 50 nm. A particularly small vertical extension 122Y of the doping region 122 contributes to an advantageously low optical absorption within the semiconductor body 10.

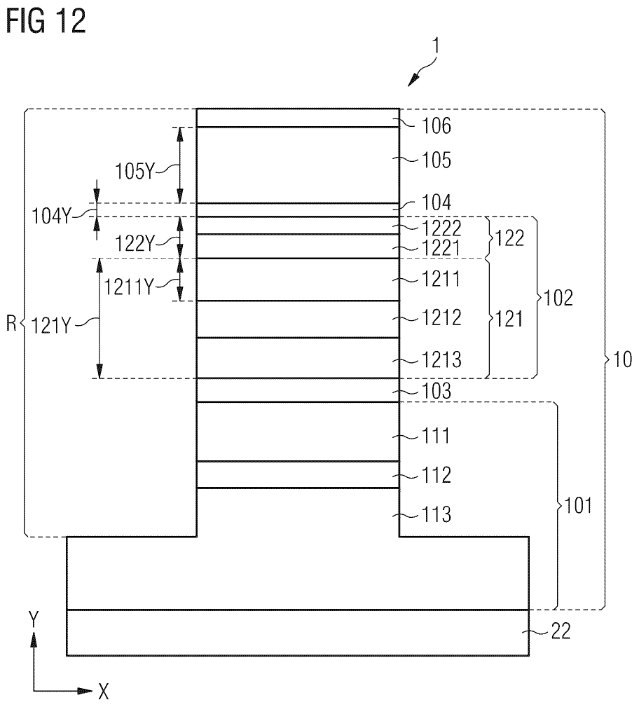

FIG. 12 shows a schematic sectional view of an optoelectronic semiconductor component 1 described herein according to a fourth exemplary embodiment. The fourth exemplary embodiment essentially corresponds to the first exemplary embodiment shown in FIG. 1. In contrast to the first exemplary embodiment, in the fourth exemplary embodiment a tunnel diode region 104 is arranged on a side of the p-doped region 102 facing away from the active region 103.

In particular, the tunnel diode region 104 has a high dopant concentration of p- and n-dopants. Preferably, the tunnel diode region 104 has an n-dopant concentration of more than 10¹⁹ cm⁻³. Further preferably, the tunnel diode region 104 has a p-dopant concentration of more than 5*10¹⁹ cm⁻³, preferably more than 10²⁰ cm⁻³. In particular, the tunnel diode region 104 has a small thickness. A thickness is considered here and in the following as an extension in the vertical direction. For example, the tunnel diode region 104 has a vertical extension 104Y of at most 50 nm, preferably of at most 30 nm and particularly preferably of at most 5 nm. Due to the high dopant concentration and the small vertical extension of the tunnel diode region 104, such a narrow space charge zone can be formed that a transport of charge carriers by means of quantum mechanical tunnel effects is made possible. Advantageously, a p-doped region with a low electrical resistance can be electrically conductively connected to an n-doped region.

The optoelectronic semiconductor component further comprises a second cladding layer 105 on a side of the tunnel diode region 104 facing away from the active region 103. The second cladding layer 105 is arranged on a side of the tunnel diode region 104 facing away from the active region 103. Preferably, the second cladding layer 105 is n-doped. The second cladding layer 105 is formed with AlGaN, for example. In particular, the second cladding layer 105 has the same composition as the first cladding layer 113. Alternatively, it can also be advantageous if the first cladding layer 113 has a lower Al concentration than the second cladding layer 105. The second cladding layer 105 has a vertical extension 105Y of between 1 nm and 2 μm, preferably between 50 nm and 800 nm and particularly preferably between 150 nm and 500 nm, for example.

The optoelectronic semiconductor component 1 additionally comprises a second contact layer 106 on a side of the tunnel diode region 104 facing away from the active region 103. The second contact layer 106 is arranged on a side of the second cladding layer 105 facing away from the active region 103. The second contact layer 106 is preferably formed with GaN, since a relatively small bandgap is advantageous in order to establish a good electrical contact to further subsequent layers. The second contact layer 106 is particularly n-doped.

By using the tunnel diode region 104, a vertical extension of the spacer region 121Y can be advantageously reduced. For example, a vertical extension of the spacer region 121Y is between 1 nm and 1 μm, preferably between 20 nm and 500 nm and particularly preferably between 50 nm and 350 nm. A smaller vertical extension of the spacer region 121Y can advantageously lead to a reduced non-radiative recombination probability.

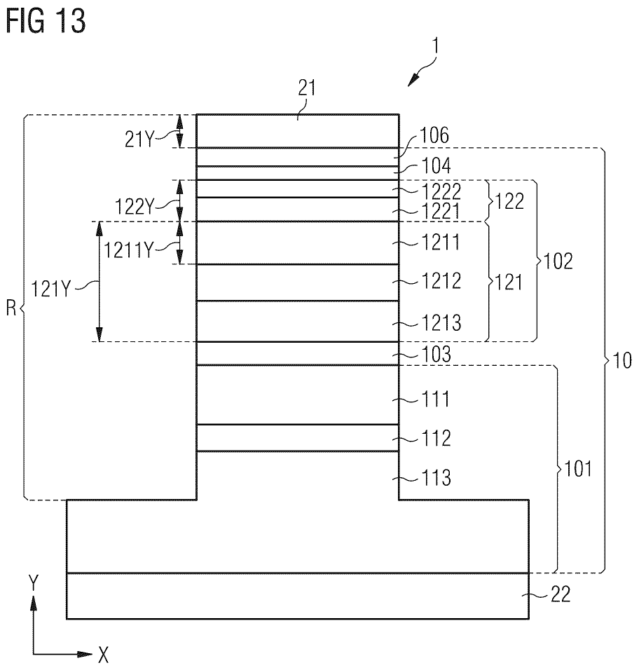

FIG. 13 shows a schematic sectional view of an optoelectronic semiconductor component 1 described herein according to a fifth exemplary embodiment. The fifth exemplary embodiment essentially corresponds to the fourth exemplary embodiment shown in FIG. 12. In contrast to the fourth exemplary embodiment, no second cladding layer 105 is arranged between the tunnel diode region 104 and the second contact layer 106. Furthermore, an electrode 21 is arranged on the side of the second contact layer 106 facing away from the active region 103. For example, the electrode 21 is formed with an indium tin oxide. In particular, a vertical extension of the electrode 21Y is between 100 nm and 300 nm, preferably between 150 nm and 250 nm. By dispensing with a second cladding layer 105, mechanical stress on the semiconductor body 10 can be advantageously reduced.

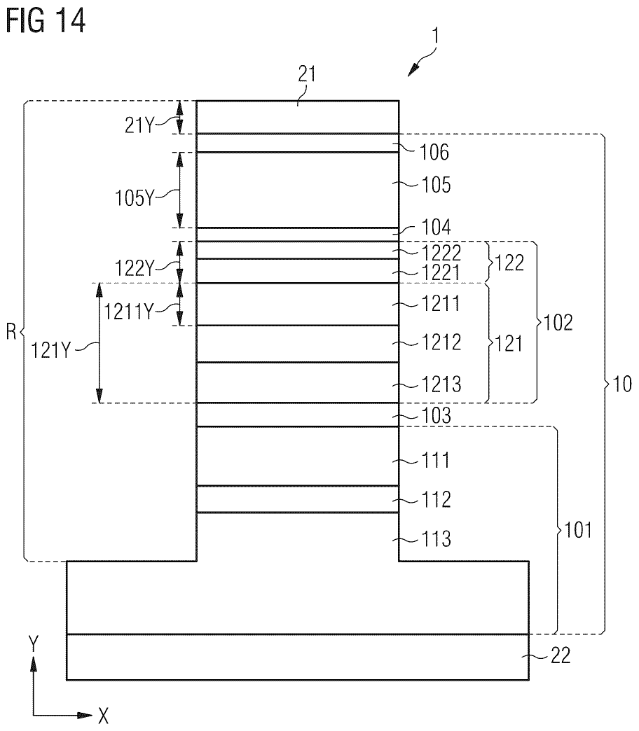

FIG. 14 shows a schematic sectional view of an optoelectronic semiconductor component 1 described herein according to a sixth exemplary embodiment. The sixth exemplary embodiment essentially corresponds to the fourth exemplary embodiment shown in FIG. 12. In addition, the optoelectronic semiconductor component 1 includes an electrode 21 arranged on the side of the second contact layer 106 facing away from the active region 103. A layer thickness of the second cladding layer 105Y can be reduced by the electrode 21. Consequently, a mechanical stress of the semiconductor body 10 is advantageously reduced.

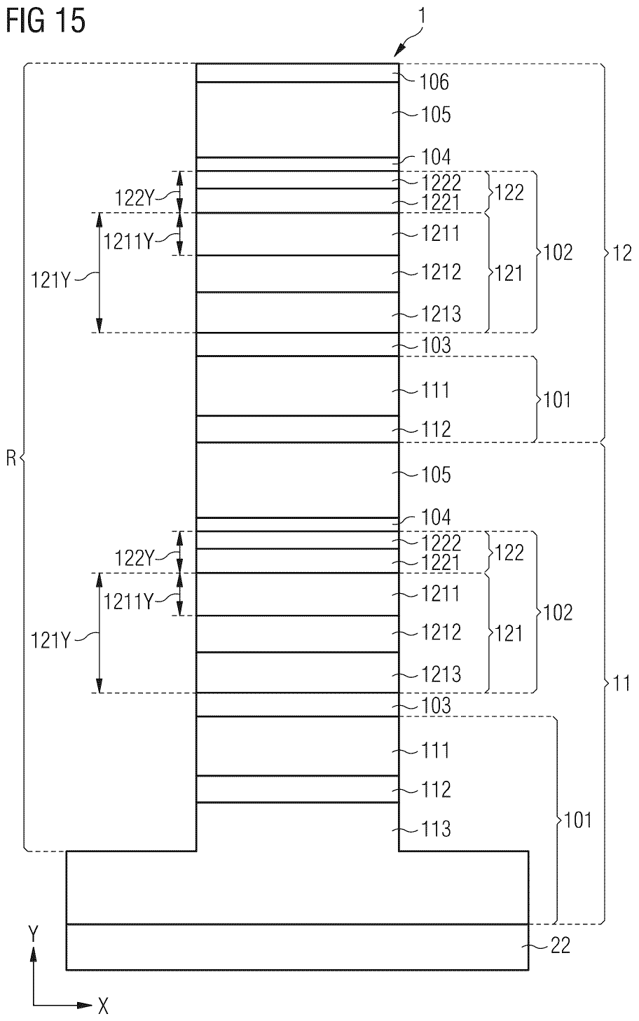

FIG. 15 shows a schematic sectional view of an optoelectronic semiconductor component 1 described herein according to a seventh exemplary embodiment. The seventh exemplary embodiment essentially corresponds to the fourth exemplary embodiment shown in FIG. 12. In contrast to the fourth exemplary embodiment, a plurality of semiconductor bodies 10 are arranged one above the other, with a tunnel diode region 104 being arranged between two semiconductor bodies 10 in each case. A first semiconductor body 11 is arranged on a substrate 22, and a second semiconductor body 12 is arranged on a side of the first semiconductor body 11 facing away from the substrate 22. The first semiconductor body 11 does not comprise a second contact layer 106. The second semiconductor body 12 does not comprise a first cladding layer 113.

By means of the tunnel diode region 104, it is possible to electrically connect a p-doped region 102 of the first semiconductor body 11 with an n-doped region 101 of the second semiconductor body 12. Stacking several semiconductor bodies 10 can result in a very compact light source with particularly high output power and slope.

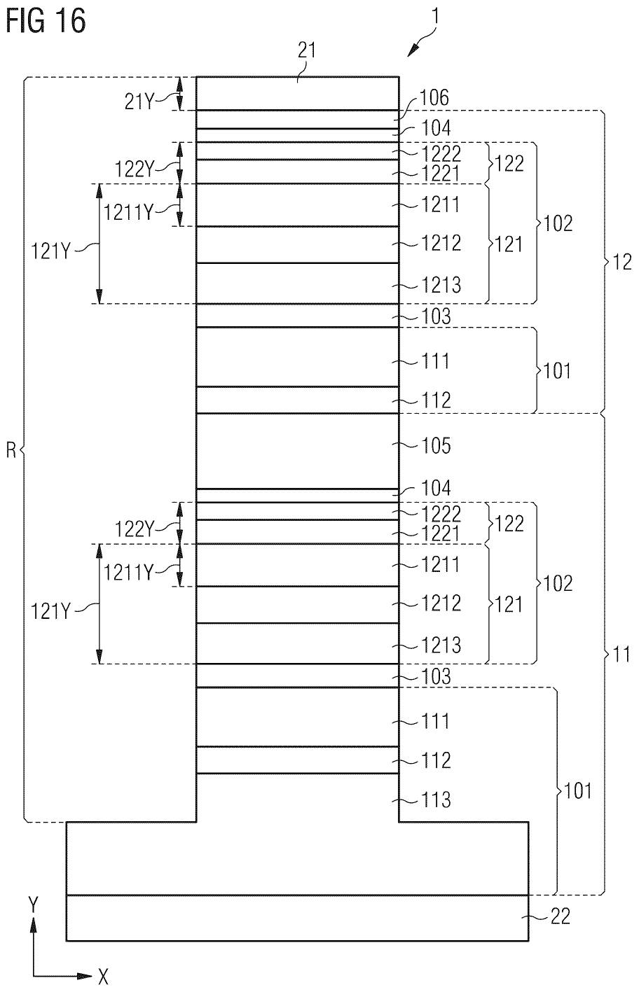

FIG. 16 shows a schematic sectional view of an optoelectronic semiconductor component 1 described herein according to an eighth exemplary embodiment. The eighth exemplary embodiment essentially corresponds to the seventh exemplary embodiment shown in FIG. 15. In contrast to the seventh exemplary embodiment, the second semiconductor body 12 does not comprise a second cladding layer 105. Furthermore, the second semiconductor body 12 comprises an electrode 21 on the side of the second contact layer 106 facing away from the substrate 22.

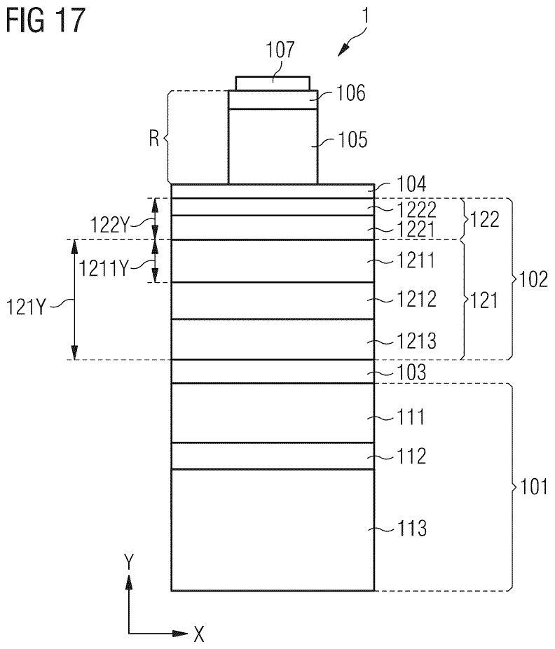

FIG. 17 shows a schematic sectional view of an optoelectronic semiconductor component 1 described herein according to a ninth exemplary embodiment. The ninth exemplary embodiment essentially corresponds to the fourth exemplary embodiment shown in FIG. 12. In contrast to the fourth exemplary embodiment, a ridge edge R extends from the second contact layer 106 to at most the electron blocking layer 1221. Advantageously, this can facilitate diffusion of hydrogen from the p-doped region 122 and the tunnel diode region 104. Advantageously, this results in an improved activation of the p-doping in the p-doped region 102 and the tunnel diode region 104. For example, the p-doping is activated by a temperature step and with the addition of oxygen.

In addition, the ninth exemplary embodiment comprises a contact element 107. The contact element 107 is arranged on a side of the second contact layer 106 facing away from the active region 103. Preferably, a lateral extension of the contact element 107 is less than a lateral extension of the active region 103. In this way, lateral mode guidance can be improved. For example, the contact element 107 is made of metal. Metal has an advantageously low electrical resistance.

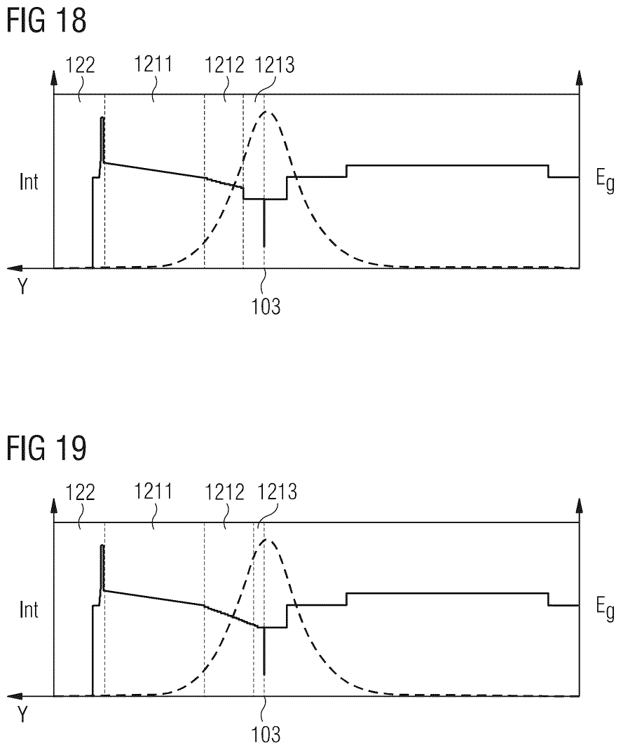

FIG. 18 shows a curve of a bandgap E_{G} of an optoelectronic semiconductor component 1 described herein according to a tenth exemplary embodiment. FIG. 18 shows a curve of a bandgap E_{G} within a spacer region 121. The bandgap E_{G} increases within the first spacer layer 1211 starting from an interface facing the active region 103. In other words, an electrical bandgap E_{G} increases within the first spacer layer 1211 with an increasing distance from the active region 103. In particular, the increase in the electrical bandgap E_{G} is caused by an increase in a proportion of aluminum in the first spacer layer 1211. Preferably, a proportion of aluminum in the first spacer layer 1211 increases with increasing distance from the active region 103. The electrical bandgap E_{G} changes along a vertical extension of the first spacer layer 1211, for example continuously or in steps. Such a shaped bandgap E_{G} within the first spacer layer 1211 advantageously results in a lower charge carrier density within the first spacer layer 1211, whereby a probability for non-radiative recombination processes is advantageously reduced.

Furthermore, FIG. 18 shows the curve of the bandgap E_{G} within the second spacer layer 1212. The bandgap E_{G} within the second spacer layer 1212 increases starting from an interface facing the active region 103. In other words, an electrical bandgap E_{G} increases within the second spacer layer 1212 with an increasing distance from the active region 103. In particular, the increase in the electrical bandgap E_{G} is caused by a decrease in a proportion of indium in the second spacer layer 1212. Preferably, a proportion of indium in the second spacer layer 1212 decreases with increasing distance from the active region 103. The electrical bandgap E_{G} changes along a vertical extension of the second spacer layer 1212, for example continuously or in steps. Such a shaped bandgap E_{G} within the second spacer layer 1212 advantageously results in a lower charge carrier density within the second spacer layer 1212, whereby a probability for non-radiative recombination processes is advantageously reduced. At the interface between the second spacer layer 1212 and the third spacer layer 1213, the bandgap E_{G} has a step.

Advantageously, the curve of the bandgap E_{G} is constant in each case within the regions in the n-conducting region 101 in the curve of the stacking direction of the semiconductor body 10. In other words, the bandgap E_{G} within the first waveguide 111, the second waveguide 112 and the first cladding layer 113 are constant in each case along their vertical extension.

FIG. 19 shows a curve of a bandgap E_{G} of an optoelectronic semiconductor component 1 described herein according to an eleventh exemplary embodiment. The eleventh exemplary embodiment essentially corresponds to the tenth exemplary embodiment shown in FIG. 18. In contrast to the tenth exemplary embodiment, the bandgap E_{G} in the interface between the second spacer layer 1212 and the third spacer layer 1213 does not have a step. In other words, a bandgap E_{G} of the second spacer layer 1212 at the interface to the third spacer layer 1213 corresponds to the bandgap E_{G} of the third spacer layer 1213. Alternatively, a third spacer layer 1213 can also be dispensed with. In this case, there is an interface between the second spacer layer 1212 and the active region 103.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1.-28. (canceled)

29. An optoelectronic semiconductor component comprising:
a semiconductor body having an n-conducting region, a p-conducting region and an active region configured to emit electromagnetic radiation, the active region arranged between the n-conducting region and the p-conducting region,
wherein the p-conducting region comprises a spacer region and a p-doped doping region,
wherein the spacer region is arranged between the doping region and the active region and comprises a first spacer layer comprising aluminum, and
wherein a vertical extension of the doping region corresponds to at most one third of a vertical extension of the spacer region.

30. The optoelectronic semiconductor component according to claim 29, wherein at least one of the following features applies:
the vertical extension of the doping region corresponds to at most one fifth of the vertical extension of the spacer region;
the spacer region comprises a second spacer layer;
an average n-dopant concentration in the spacer region is less than 10²⁰ cm⁻³; and
an average p-dopant concentration in the spacer region is less than 10¹⁹ cm⁻³.

31. The optoelectronic semiconductor component according to claim 29,
wherein the n-conducting region comprises a first waveguide, a second waveguide and a first cladding layer, and
wherein the first waveguide and the second waveguide are arranged between the first cladding layer and the active region.

32. The optoelectronic semiconductor component according to claim 31, wherein the first cladding layer has a higher n-doping than the first waveguide and the second waveguide.

33. The optoelectronic semiconductor component according to claim 31,
wherein an aluminum content of the first spacer layer is at most as high as an aluminum content of the first cladding layer, or
wherein an aluminum content of the first cladding layer is at most as high as an aluminum content of the first spacer layer.

34. The optoelectronic semiconductor component according to claim 29, wherein the doping region comprises an electron blocking layer, a ramp region and a first contact layer formed with a semiconductor material selected from the following group: GaN, AlGaN, InGaN, or AlInGaN.

35. The optoelectronic semiconductor component according to claim 34,
wherein the first spacer layer comprises a semiconductor material having the general formula AlₓIn_{y}Ga_{1-x-y}N,
wherein the electron blocking layer comprises a semiconductor material having the general formula Al_{q}In_{z}Ga_{1-q-z}N, and
wherein (q−z)−(x−y)≥0.12 applies.

36. The optoelectronic semiconductor component according to claim 34, wherein the ramp region has a decreasing aluminum content in a direction away from a side of the electron blocking layer facing the active region.

37. The optoelectronic semiconductor component according to claim 34,
wherein the ramp region has a starting point at an interface to the electron blocking layer and an end point at an interface to the first contact layer, and
wherein an aluminum content at the starting point corresponds at most to an aluminum content of the electron blocking layer.

38. The optoelectronic semiconductor component according to claim 34,
wherein the ramp region has a starting point at an interface to the electron blocking layer and an end point at an interface to the first contact layer, and
wherein an aluminum content at the end point corresponds at least to the aluminum content of the first contact layer.

39. The optoelectronic semiconductor component according to claim 29, wherein at least one of the following features applies:
the first spacer layer is a semiconductor material with the general formula AlₓIn_{y}Ga_{1-x-y}N, where 0≤x≤0.15;
a first waveguide is formed with a material according to the following composition: InₙGa₁₋ₙN, and
a third spacer layer is formed with a material according to the following composition: InₘGa₁₋ₘN, wherein the following relationship applies to a difference in indium content: |n−m|≥0.003;
a ridge edge extends from a second region at least completely through the active region;
the vertical extension of the doping region is less than 150 nm;
a vertical extension of the first spacer layer is between 1 nm and 2000 nm;
the doping region is followed by an electrode on a side facing away from the active region, wherein the electrode is formed with a transparent conductive oxide;
a bandgap within the first spacer layer increases starting from an interface facing the active region; or
a bandgap within a second spacer layer increases starting from an interface facing the active region.

40. The optoelectronic semiconductor component according to claim 29, further comprising a tunnel diode region arranged on a side of the p-doped region facing away from the active region.

41. The optoelectronic semiconductor component according to claim 40, further comprising a second cladding layer arranged on a side of the tunnel diode region facing away from the active region.

42. The optoelectronic semiconductor component according to claim 40, further comprising a second contact layer arranged on a side of the tunnel diode region facing away from the active region.

43. The optoelectronic semiconductor component according to claim 40,
wherein a plurality of semiconductor bodies is arranged one above the other, and
wherein the tunnel diode region is arranged between two semiconductor bodies in each case.

44. A method for producing the optoelectronic semiconductor component according to claim 29, the method comprising:
providing a p-doped doping region and at least partially providing a tunnel diode region; and
annealing at a temperature above 300° C. to activate the p-doping.

45. The method according to claim 44, wherein annealing comprising adding oxygen.

46. An optoelectronic semiconductor component comprising:
a semiconductor body having an n-conducting region, a p-conducting region and an active region configured to emit electromagnetic radiation, the active region arranged between the n-conducting region and the p-conducting region,
wherein the p-conducting region comprises a spacer region and a p-doped doping region,
wherein the spacer region is arranged between the doping region and the active region and comprises a first spacer layer comprising aluminum,
wherein a vertical extension of the doping region corresponds to at most one third of the vertical extension of the spacer region, and
wherein the doping region comprises an electron blocking layer, a ramp region and a first contact layer formed with a semiconductor material selected from the following group: GaN, AlGaN, InGaN, or AlInGaN.

47. A method for producing an optoelectronic semiconductor component, the method comprising:
providing a p-doped doping region and at least partially providing a tunnel diode region; and
annealing at a temperature above 300° C. to activate the p-doping.
